(19) United States
(12) Patent Application Publication
(10) Pub. No.: US 2010/0288351 A1
(43) Pub. Date: Nov. 18, 2010

(54) THIN-FILM SOLAR CELL

(76) Inventors: Burkhard Speit, Mainz (DE); Eveline Rudigier-Voigt, Mainz (DE); Wolfgang Mannstadt, Muenster-Sarmsheim (DE); Silke Wolff, Hueckeswagen (DE)

Correspondence Address: MICHAEL J. STRIKER, 103 EAST NECK ROAD, HUNTINGTON, NY, 11743, US

(21) Appl. No.: 12/775,912

(22) Filed: May 7, 2010

(30) Foreign Application Priority Data
May 12, 2009 (DE) 10 2009 020 955.7
Oct. 28, 2009 (DE) 10 2009 050 988.7

(51) Int. Cl. H01L 31/02; H01L 31/00; H01L 31/0203

(52) U.S. Cl. 136/256; 136/252; 136/259

(57) ABSTRACT

The thin-film solar cell includes at least one Na₂O-containing multicomponent substrate glass. The substrate glass contains less than 1% by weight of B₂O₃, less than 1% by weight of BaO and a total of less than 3% by weight of CaO+SrO+ZnO, the molar ratio of the substrate glass components, (Na₂O+K₂O)/(MgO+CaO+SrO+BaO), is greater than 0.95, the molar ratio of the substrate glass components SiO₂/Al₂O₃ is less than 7 and the substrate glass has a glass transition temperature Tg of greater than 550° C., in particular greater than 600° C. The thin-film solar cells made with this substrate glass have improved efficiencies in comparison to thin-film solar cells of the prior art.

### CROSS-REFERENCE

The subject matter described and claimed herein below is also described in German Patent Application No. 10 2009 020 955.7, filed on May 12, 2009 in Germany, and German Patent Application No. 10 2009 050 988.7, filed on Oct. 28, 2009 in Germany. These German Patent Applications provide the basis for respective claims of priority of invention for the thin-film solar cell and process claimed herein below under 35 U.S.C. 119 (a)-(d).

### BACKGROUND OF THE INVENTION

1. The Field of the Invention

The invention relates to a thin-film solar cell.

2. The Description of the Related Art

The future market development of photovoltaics, in particular for photovoltaic plants connected to the grid, is critically dependent on the cost reduction potential in the production of solar cells. A great potential is seen in the production of thin-film solar cells, since significantly less photoactive material is required for efficient conversion of sunlight into electricity than in the case of conventional crystalline, silicon-based solar cells. In thin-film solar cells, photoactive semiconductor materials, especially indirect semiconductors such as silicon-based materials (a distinction is made here between amorphous or microcrystalline and crystalline silicon or layers thereof) and direct semi-conductors such as highly absorbing compound semiconductors of groups II to VI of the Periodic Table of the Elements (for example CdTe) or of groups Ito III to VI2, e.g. Cu(IN₁₋ₓGaₓ)(Se_{1-y}S_{y})₂ (CIGS) are deposited on inexpensive, sufficiently heat-resistant substrates, e.g. molybdenum-coated substrate glasses, in layers of a few μm in thickness. The cost reduction potential is especially based on the lower semiconductor material consumption and the great ability to automate production. However, the efficiencies of commercial thin-film solar cells which have hitherto been achieved remain significantly behind those of crystalline, silicon-based solar cells (thin-film solar cells: about 10-15% efficiency; crystalline silicon-based solar cells comprising silicon wafers: about 15-18% efficiency).

Apart from solar cells comprising soda-lime float glasses as substrate glass for thin-film photovoltaic applications, solar cells having other substrate glass types or further substrate glass types which are said to be suitable for photovoltaics are also known.

DE 699 16 683 T2 discloses substrate glasses for VDUs having a coefficient of thermal expansion of from 6.0×10⁻⁶/K to 7.4×10⁻⁶/K in the temperature range from 50° C. to 350° C. which are also said to be suitable for solar cells.

Solarization-stable aluminosilicate glasses having a total content of CaO, SrO and BaO of from 8 to <17% by weight as substrate for solar collectors are disclosed in EP 0 879 800 A1.

Thin-film solar cells, in particular on the basis of compound semiconductors, comprising a glass substrate having a coefficient of thermal expansion of from 6×10⁻⁶/K to 10×10⁻⁶/K are disclosed in JP 11-135819 A. The glass substrate here has the following composition in percent by weight: SiO₂ from 50 to 80, Al₂O₃ from 5 to 15, Na₂O from 1 to 15, K₂O from 1 to 15, MgO from 1 to 10, CaO from 1 to 10, SrO from 1 to 10, BaO from 1 to 10, ZrO₂ from 1 to 10, and is characterized by an “Annealing Point” (temperature at a viscosity of the glass of 10¹³ dPas) of greater than 550° C.

Substrate glasses for use in thin-film photovoltaics, in particular on the basis of compound semiconductors, are disclosed in DE 100 05 088 C1. The glasses have a B₂O₃ content of from 1 to 8% by weight and a total content of alkaline earth metal oxides (MgO, CaO, SrO and BaO) of from 10 to 25% by weight.

### SUMMARY OF THE INVENTION

It is an object of the invention to provide a thin-film solar cell which is improved over the prior art. The solar cell of the invention should also be able to be produced economically by known processes and it should have a higher efficiency.

This object is achieved by a thin-film solar cell comprising at least one Na₂O-containing multicomponent substrate glass, The Na₂O-containing multicomponent substrate glass (substrate glass) must have at least all of the following features:
a content of the substrate glass components of less than 1% by weight of B₂O₃, of less than 1% by weight of BaO and of a total of less than 3% by weight of CaO+SrO+ZnO,
a molar ratio of the substrate glass components, Na₂O+K₂O)/(MgO+CaO+SrO+BaO, of greater than 0.95 (i.e. the substrate glass contains at least Na₂O or K₂O and at least MgO or CaO or SrO or BaO),
a molar ratio of the substrate glass components SiO₂/Al₂O₃ of less than 7 (i.e. the substrate glass contains SiO₂ and Al₂O₃),
a glass transition temperature Tg (temperature at a viscosity of the glass of 10^{14.5} dPas in accordance with DIN 52324) of the substrate glass of greater than 550° C., in particular greater than 600° C.

A thin-film solar cell will hereinafter be referred to as a solar cell in the interests of simplicity, including in the dependent claims. For the purposes of the present patent application, the term substrate glass can also encompass a superstrate glass.

For the purposes of the present invention, the expression Na₂O-containing multicomponent substrate glass means that the substrate glass can contain not only Na₂O, but also additional composition components, such as B₂O₃, BaO, CaO, SrO, ZnO, K₂O, MgO, SiO₂ and Al₂O₃, and also nonoxidic components, e.g. anionically bound components such as F, P, N.

Such solar cells according to the invention can be produced by known processes, with the process parameters possibly having to be adapted. Known processes for producing the semiconductor layers on the substrate glass or on a previously coated substrate glass are, for example, the sequential process (reaction of metallic layers in a chalcogen atmosphere), co-vaporization (virtually simultaneous vaporization of the individual elements or element compounds) and liquid coating processes with a subsequent heating step in a chalcogen atmosphere. It has surprisingly been found that, particularly in the deposition of the semiconductor layers, it is possible to use far higher process temperatures than in the case of conventional soda-lime substrate glasses without the substrate glass becoming disadvantageously deformed for a later lamination process, and the solar cells of the invention have an efficiency which is over 2% absolute higher than that of known solar cells having soda-lime substrate glasses.

It has been found that a B₂O₃ content of the substrate glass of above 1% by weight has an adverse effect on the efficiency Of the solar cell. Boron atoms can presumably migrate from the substrate glass into the semiconductor by vaporization or diffusion. This presumably leads to defects within the semi-conductor layer which are electrically active and cause increased recombination, as a result of which the performance of the solar cell is reduced.

On the other hand, a content of BaO of less than 1% by weight and a content of one or all of the following substrate glass components CaO, SrO and/or ZnO of less than 3% by weight (sum of CaO+SrO+ZnO<3% by weight, preferably <0.5% by weight) have a positive effect on the mobility of the sodium ions in the substrate glass during production of the solar cell, which leads to an increase in the efficiency of the solar cell. It is important that the molar ratio of the substrate glass components, (Na₂O+K₂O)/(MgO+CaO+SrO+BaO), must be greater than 0.95, preferably from >0.95 to 6.5, in order to increase the efficiency of the solar cell of the invention compared to a known solar cell.

The solar cell of the invention preferably comprises a substrate glass, which contains less than 0.5% by weight of B₂O₃, in particular no B₂O₃ apart from unavoidable traces. Furthermore, the solar cell of the invention preferably comprises a substrate glass which contains less than 0.5% by weight of BaO, in particular no BaO apart from unavoidable traces. For particular solar cells, it is advantageous for the substrate glasses to be free of B₂O₃ and/or BaO apart from unavoidable traces, in particular for less than 1000 ppm of B₂O₃ and/or less than 1000 ppm of BaO to be present.

In a further preferred embodiment of the invention, the solar cell comprises a substrate glass which contains a total of less than 2% by weight of CaO+SrO+ZnO in the substrate glass components, which leads to a higher mobility of the alkaline metal ions in the substrate glass during production of the solar cell and thus to a more effective solar cell.

The solar cell preferably comprises a substrate glass containing at least 5% by weight of Na₂O, in particular at least 8% by weight of Na₂O.

In a further preferred embodiment, the solar cell comprises a substrate glass containing not more than 18% by weight of Na₂O and preferably not more than 16% by weight of Na₂O.

The molar ratio of the substrate glass components SiO₂/Al₂O₃ is preferably less than 6 and greater than 5.

According to the invention, the solar cell preferably has an aluminosilicate substrate glass, in particular an aluminosilicate substrate glass having a glass transition temperature Tg of >550° C., which comprises the following composition components (in mol %):

| | |
|---|---|
| SiO₂ | 63-67.5 |
| B₂O₃ | 0 |
| Al₂O₃ | 10-12.5 |
| Na₂O | 8.5-15.5 |
| K₂O | 2.5-4.0 |
| MgO | 3.0-9.0 |
| BaO | 0 |
| CaO + SrO + ZnO | 0-2.5 |
| TiO₂ + ZrO₂ | 0.5-1.5 |
| CeO₂ | 0.02-0.5 |
| As₂O₃ + Sb₂O₃ | 0-0.4 |
| SnO₂ | 0-1.5 |
| F | 0.05-2.6; |

wherein the components are present in the substrate glass in the following molar ratios:

| | |
|---|---|
| SiO₂/Al₂O₃ | 5.0-6.8 |
| Na₂O/K₂O | 2.1-6.2 |
| Al₂O₃/K₂O | 2.5-5.0 |
| Al₂O₃/Na₂O | 0.6-1.5 |
| (Na₂O + K₂O)/(MgO + CaO + SrO) | 0.95-6.5. |

Furthermore the solar cell of the invention preferably has an aluminosilicate substrate glass which comprises the following composition components (in mol %):

| | |
|---|---|
| SiO₂ | 63-67.5 |
| B₂O₃ | 0 |
| Al₂O₃ | 10-12.5 |
| Na₂O | 8.5-17 |
| K₂O | 2.5-4.0 |
| MgO | 3.0-9.0 |
| BaO | 0 |
| CaO + SrO + ZnO | 0-2.5 |
| MgO + CaO + SrO + BaO | ≧3 |
| TiO₂ + ZrO₂ | 0-5, in particular 0-4, |
| | preferably 0.25-1.5 |
| CeO₂ | 0-0.5, in particular 0.02-0.5 |
| As₂O₃ + Sb₂O₃ | 0-0.4 |
| SnO₂ | 0-1.5 |
| F | 0-3, in particular 0.05-2.6; |

wherein the components are present in the substrate glass in the following molar ratios:

| | |
|---|---|
| SiO₂/Al₂O₃ | >5 |
| Na₂O/K₂O | 2.1-6.2 |
| Al₂O₃/K₂O | 2.5-5.0 |
| Al₂O₃/Na₂O | 0.6-1.5 |
| (Na₂O + K₂O)/(MgO + CaO + SrO) | >0.95. |

Apart from these preferred compositions, the substrate glass can contain additional components customary in glass production, e.g. refining agents, in the customary amounts, in particular up to 1.5% by weight of sulphate and/or up to 1% by weight of chloride.

Furthermore, it is necessary for the solar cell to have a substrate glass having a coefficient of thermal expansion α_{20/300} of greater than 7.5×10⁻⁶/K, in particular from 8.0×10⁻⁶/K to 9.5×10⁻⁶/K, in the temperature range from 20° C. to 300° C. Thus, it has been found to be advantageous to match the coefficient of thermal expansion of the substrate glass to that of the photoactive semiconductor layer, for example a CIGS layer.

In a particular embodiment of the invention, the solar cell has a substrate glass which has an electrical conductivity of greater than 17×10⁻¹² S/cm at 25° C., with the electrical conductivity of the substrate glass at 250° C. being greater by a factor of 10⁴, preferably greater by a factor of 10⁵ and particularly preferably greater by a factor of 10⁶, than the electrical conductivity of the substrate glass at 25° C.

If Si-based or CdTe-based thin-film solar cells are produced according to the invention, the substrate glasses described are particularly well suited, since in the case of these substrate glasses ions can be exchanged, preferably by a chemical route. The sodium ions which are undesirable in these cases can thus easily be replaced by other ions, e.g. lithium or potassium ions. These substrate glasses are therefore also suitable for special CIGS solar cells in which Na is added as dopant (e.g. as NaF₂), since they have an intrinsic Na barrier due to the ion-exchanged surface; an additional layer acting as a barrier layer is not necessary. For this purpose, the substrate glasses are, for example, dipped into a potassium salt melt, e.g. a KNO₃ melt at from 400° C. to 520° C., for a particular time interval, which is determined essentially by the thickness of the exchange layer in the substrate. If dipping is carried out, for example, at 450° C. for 10 hours, a virtually sodium ion-free surface layer having a surface depth of at least 20 μm and having potassium ions on the sodium ion sites is formed on the surface of the substrate glass.

These ion exchange properties can also be utilized in fracture-resistant covering glasses for these solar cells according to the invention, with a compressive stress being generated in the surface by replacement of the smaller sodium ion by the larger potassium ion. This significantly improves the mechanical strength of the covering glass at an unaltered transparency.

In the solar cells of the invention, the sodium ions of the substrate glass are therefore preferably replaced at least partly by other cations, in particular by potassium ions, to a surface depth of 20 μm, so that the sodium ion content in the surface layer is reduced compared to the total sodium ion content of the substrate glass.

The substrate glass of a solar cell according to the invention is preferably coated with at least one molybdenum layer, with the molybdenum layer preferably having a thickness of from 0.25 to 3.0 μm, particularly preferably from 0.5 to 1.5 μm.

The solar cell is preferably a thin-film solar cell based on silicon or a thin-film solar cell based on compound semiconductor material, for example CdTe, CIS or GIGS.

Furthermore, it has been found that the solar cell can be a planar, curved, spherical or cylindrical thin-film solar cell.

The solar cell of the invention is preferably an essentially planar (flat) solar cell or an essentially tubular solar cell, with flat substrate glasses or tubular substrate glasses preferably being used. The solar cell of the invention is in principle not subject to any restrictions with respect to its shape or the shape of the substrate glass.

In the case of a tubular solar cell, the external diameter of a tubular substrate glass of the solar cell is preferably from 5 to 100 mm and the wall thickness of the tubular substrate glass is preferably from 0.5 to 10 mm.

In a further preferred embodiment of the invention, the solar cell has functional layers. The functional layers of the solar cell preferably comprise conductive and transparent conductive materials, photosensitive compound semiconductor materials, buffer materials and/or metallic back contact materials. If at least two solar cells are connected in series, a thin-film photovoltaic module is formed and is protected from environmental influences by encapsulation, in particular by encapsulation with SiO₂, plastics and films, e.g. EVA (ethylene-vinyl acetate), surface coating layers or/and a further substrate glass. The further substrate glass can be the same substrate glass as is already present in the solar cell or else can be another substrate glass, e.g. a substrate glass which has been pre-stressed by ion exchange.

The solar cell preferably has at least one photoactive semiconductor which has been applied to the substrate glass or a previously coated substrate glass at a temperature of >550° C. This temperature is preferably less than the glass transition temperature Tg of the substrate glass.

The solar cell is preferably a thin-film solar cell based on compound semiconductors, as will be illustrated by way of example below.

The thin-film solar cells according to the invention based on II-VI or I-III-VI compound semiconductors, such as CdTe or CIGS of the general formula

Cu(In₁₋ₓGaₓ)(S_{1-y}Se_{y})₂

have a better crystallinity compared to the prior art and thus an increased open circuit voltage and a higher efficiency.

These compound semiconductors applied in the form of thin layers or packets of layers to the substrate glasses meet important prerequisites such as in the case of CIGS a band gap (1.0<E_{g}<2.0 eV) which is very well matched to the spectrum of sunlight by mixing of the ternary compounds and a high absorption of incident light (absorption coefficient >2×10⁴ cm⁻¹) for use thereof in solar cells.

Thin, polycrystalline layers or packets of layers of easily variable Cu(In₁₋ₓGaₓ)(S_{1-y}Se_{y})₂ compositions can in principle be produced in a number of stages by a series of processes (e.g. simultaneous vapor deposition of the elements, sputtering with a subsequent reactive gas step, CVD, MOCVD, co-vaporization, electro-deposition or liquid deposition with a subsequent heating step in a chalcogen atmosphere, etc.). As such, CIGS layers or packets of layers have intrinsic p conduction. The p/n junction in such material systems is then formed by introducing a thin buffer layer (e.g. a CdS layer or the like having a thickness of a few nanometers) and subsequently deposited n-conducting, transparent oxides (TCO=Transparent Conductive Oxides, e.g. ZnO or ZnO(AI)). To avoid parasitic absorption the buffer layer is made very thin, while the TCO layer additionally must have a high electrical conductivity in order to ensure virtually loss-free output of the current.

The efficiencies of Cu(In₁₋ₓGaₓ)(S_{1-y}Se_{y})₂ cells produced on a pilot or production scale are at present in the range from 10 to 15%. Customary module formats made up of individual solar cells connected in series in a monolithically integrated fashion have a size on the order of 60×120 cm² while ensuring the homogeneity of the layers (thickness, composition) over the entire module area.

FIG. 1 shows the schematic structure of an exemplary planar thin-film solar cell according to the invention having a pn heterojunction based on Cu(In₁₋ₓGaₓ)(S_{1-y}Se_{y})₂.

In one embodiment as shown in FIG. 1, a substrate glass having the composition of example 2 in the Table II presented herein below and a Tg of 632° C. was produced by the float process and cut into pieces by cemented carbide cutting tools. The substrate glass plates obtained in this way were cleaned in a standard industrial process and coated with the following layer system: substrate glass/back contact (molybdenum via sputtering technology)/absorber (CIGS, with the metallic layers having been applied by means of sputtering and subsequently been reacted in a chalcogen-containing atmosphere by means of “rapid thermal processing”, RTP for short, with T_{annealing}>550° C.)/buffer layer (CdS via chemical bath deposition)/window layer (i-ZnO/ZnO: Al via sputtering technology). Depending on the embodiment, module or solar cell, an integrated series connection was achieved via various intermediate structuring steps or a front grid applied by screen printing. Compared to a solar cell on a conventional soda-lime glass substrate, a more than 15% higher efficiency was achieved in this way (efficiency of solar cell with soda-lime glass substrate=15.5%; efficiency of solar cell with exemplary substrate glass 2 as substrate glass=18%). The efficiency was determined via a current-potential curve using a sun simulator.

FIG. 2 shows essentially the structure of FIG. 1 but with the thin-film solar module composed of a plurality of thin-layer solar cells connected in series being protected against environmental influences by encapsulation. In a particular embodiment, a barrier layer, for example SiN via sputtering technology, can be applied between the substrate glass and the back contact layer and also an Na-containing intermediate layer, for example NaF via vapor deposition, between back contact layer and absorber layer; the latter is not shown in FIG. 2. The other layers in FIG. 2 correspond to those of FIG. 1. To carry out encapsulation, a laminating film, for example an EVA film, and a hardened commercially available covering glass, for example a low-iron soda-lime glass, were positioned over the module having integrated serial connection and laid down and subsequently laminated in a thermal curing step. Typical lamination temperatures are in the range from 50 to 200° C.

FIG. 3 in principle shows the same layer structure of the compound semiconductor as in FIG. 1 but on the surface of an inner glass tube as substrate glass (tube diameter about 15-18 mm) which is then coated with the solar cell in a further outer glass tube having a larger diameter (about 25 mm) and a suitable filling liquid (e.g. silicone oil) between the inner tube and installed in the outer tube. To increase the efficiency, a reflecting white surface behind the tubes can be necessary in the shade.

The substrate glass preferably comprises an aluminosilicate glass as is known, for example, from the documents DE 196 16 633 C1 and DE 196 16 679 C1, but it must have the composition and properties recited in the appended claims. Also its coefficient of thermal expansion α_{20/300} must be matched to that of the semiconductor. A contact layer, here of metallic molybdenum, is applied to the substrate glass. The actual photoactive semiconductor is located thereon. On top of this, a buffer layer of, for example, CdS and on top of that a window (here a transparent, conductive layer (TCO)) through which sunlight can penetrate through to the semiconductor are applied.

An important requirement which a suitable substrate glass must meet results from the temperatures prevailing in the coating process. To achieve high deposition rates or a very good crystalline quality of the layers, the phase diagram of Cu(In₁₋ₓGaₓ)(S_{1-y}Se_{y})₂ indicates that temperatures above at least 550° C. are necessary. Higher temperatures, in particular temperatures above 600° C., lead to even better results with respect to the deposition rate and crystallinity of the layers. Since the substrate glass to be coated is generally positioned very close to a radiation source, in particular embodiments suspended over the vaporization sources used in the coating process, the substrate glass should have a very high heat resistance. As a rough guide, the glass transition temperature (T_{g}) in accordance with DIN 52 324 of the glass should accordingly be above at least 550° C. The higher the T_{g}, the lower the risk of deformation of the substrate glass during coating at temperatures close to Tg. A process temperature below T_{g} also prevents introduction of stresses into the substrate glass and thus into the layer system as a result of rapid cooling, which is usually the case in CIGS coating processes.

Not only the glass transition temperature (T_{g}), but also the viscosity behavior up to the softening temperature (ST), defined as the temperature of the glass at a glass viscosity of 10^{7.6} dPas in accordance with DIN 52 312, has to be taken into account, with a very large difference between T_{g} and ST (“long glass”) reducing the risk of thermal deformation of the substrate at coating temperatures above 600° C.

To prevent splitting-off of the layer systems on cooling after the coating process, the substrate glass also has to be matched to the thermal expansion of the back contact (e.g. molybdenum, about 5×10⁻⁶/K) and even better to the semiconductor layer deposited thereon (e.g. about 8.5×10⁻⁶/K for CIGS).

Furthermore, it is known that sodium can be incorporated into the semiconductor so as to increase the efficiency of the solar cell as a result of improved chalcogen incorporation into the crystal structure of the semiconductor. The substrate glass therefore has not only to serve as support material but also has an additional function: namely the targeted release, both in terms of time and physical location (homogeneously over the area of the coating), of sodium. The glass should release sodium ions/atoms at temperatures around T_{g}, which requires increased mobility of the sodium ions in the glass. As an alternative, a barrier layer (e.g. an Al₂O₃ layer) which completely prevents diffusion of sodium ions can be applied to the glass surface before coating with molybdenum. Sodium ions then have to be added separately (e.g. in the form of NaF₂) in a further process step, which increases process times and costs.

In addition, attention has to be paid to sufficient chemical resistance against environmental influences, in particular water (moisture, wetness, rain), because of the usual placement of the solar cells (outdoors) and also against other aggressive reagents which may be used in the production process. The layers themselves are protected from the environment by encapsulation with SiO₂, plastic, surface coatings and/or a covering glass.

Table I below shows properties of substrate glasses for CIGS thin-film solar cells compared to the prior art, which are suitable for the solar cells of the invention.

TABLE I
PROPERTIES OF SUBSTRATE GLASSES

| | | | Prior art, | |
|---|---|---|---|---|
| | | Substrate | Soda-lime | |
| | Unit/Measured | Glass for the | Substrate | Advantage Over |
| Property | Parameter | Invention | Glass | the Prior Art |
| Coefficient of | ×10⁻⁶ | 7.5-9.5 | 7.3 | Matching to the |
| thermal expansion | | | | thermal expansion |
| α_{20/300} | | | | of Mo (α_{CIGSe} = 8.5) |
| Glass transition | ° C. | >600, | 555 | Matching to the |
| temperature Tg | | as high as | | thermal deposition |
| | | possible | | processes as per |
| | | | | the phase diagram |
| Softening | ° C. | 900-1000 | 850 | Prevention of |
| temperature ST | | | | deformation at |
| | | | | temperatures |
| | | | | around Tg |
| Maximum | ° C. | >600 | 530 | Improvement in |
| substrate glass | | | | the crystal growth |
| temperature | | | | conditions of the |
| during coating | | | | semiconductors |
| Sodium Ion | % by weight | >10 | >11 | High content and |
| Content | | | | high sodium ion |
| | | | | mobility |
| Hydrolytic | μg/g of Na₂O | ≦2 | ≦3 | Better than soda- |
| glass (DIN) | equivs. | | | lime glass |
| Content of | % by weight | B-, Ba-, As- | B-, Ca-, Fe- | No semiconductor |
| B₂O₃, CaO, | | Fe-free | containing | poisons in the |
| BaO, As₂O₃, | | | | process |
| Fe₂O₃ | | | | |

Surprisingly, boron- and barium-free aluminosilicate glasses in particular meet the requirements for use as substrate glass for thin-film photovoltaics, since, for example in high-temperature CIGS production technology, substrate glass temperatures of up to 700° C. are reached during coating. In particular, efficiencies of CIGS thin-film solar cells which were more than 2% absolute above those of the prior art were achieved by means of the properties according to the invention of the substrate glasses, i.e. an efficiency of 14% was achieved instead of, for example, 12% using a conventional substrate glass.

It has surprisingly also been found that these glasses have a high homogeneity with respect to bubble content on melting under oxidizing conditions when nitrates of the alkali metal and/or alkaline earth metal components, e.g. KNO₃, Ca(NO₃)₂, are used.

Large bubbles, i.e. bubbles which are visible to the naked eye (diameter >80 μm), are counted by the naked eye in a polished glass cube having an edge length of 10 cm. Size and number of smaller bubbles are measured/counted in 10 cm×10 cm×0.1 cm glass plates having a good surface polish by means of a microscope at a magnification of 400-500×.

Examples of the composition and properties of the substrate glass used in the solar cells of the invention may be found in Table II below (composition of the glasses in mol %).

The glasses were melted from conventional raw materials, i.e. carbonates, nitrates, fluorides and oxides of the components, in 4 litre platinum crucibles. The raw materials were introduced at melting temperatures of 1580° C. over a period of 8 hours and subsequently maintained at this temperature for 14 hours. The glass melt was subsequently cooled while stirring to 1400° C. over a period of 8 hours and subsequently cast into a graphite mold, which was preheated to 500° C. This casting mold was introduced immediately after casting into a cooling oven which has been preheated to 650° C. and cooled down at 5° C./min to room temperature. The glass specimens necessary for the measurements were subsequently cut from this block.

Apart from the known methods of determining the typical glass properties, the determination of the conductivity is of particular importance here. The dielectric measurements were carried out using the impedance spectrometer alpha-Analyser from Firma Novocontrol, Limburg, and the associated temperature control unit. In the measurement, a usually round plate of the glass specimen having a diameter of typically 40 mm and a thickness of from about 0.5 to 2 mm is provided on both sides with conductive silver contacts. The specimen is clamped from the upper side and underside by means of gilded brass contacts in a specimen holder and placed in a cryostat. The electrical resistance and the capacitance of the arrangement can then be measured as a function of frequency and temperature by balancing of a bridge. In the case of known geometries, the conductivity and the dielectric constant of the material can then be determined.

TABLE II
Examples Of Glass Compositions In Mol %, Molar Ratios And Properties Of
Substrate Glasses Which Are Suitable For The Solar Cell Of The Invention

| Composition | Glass 1 | Glass 2 | Glass 3 | Glass 4 | Glass 5 | Glass 6 | Glass 7 |
|---|---|---|---|---|---|---|---|
| SiO₂ | 65.04 | 67.32 | 63.6 | 63.67 | 66.26 | 66.83 | 66.36 |
| Al₂O₃ | 10.1 | 11.18 | 11.91 | 9.94 | 10.91 | 10.91 | 12.28 |
| Na₂O | 8.66 | 13.58 | 12.49 | 15.82 | 11.3 | 11.3 | 12.82 |
| K₂O | 2.68 | 3.17 | 3.48 | 2.89 | 3.82 | 3.82 | 3.82 |
| MgO | 8.62 | 3.29 | 6.51 | 3.97 | 3.25 | 3.25 | 3.25 |
| BaO | 0 | 0 | 0 | 0 | 0 | 0 | 0 |
| B₂O₃ | 0 | 0 | 0 | 0 | 0 | 0 | 0 |
| CaO + SrO + | 1.25 | 0.24 | 0.47 | 0.14 | 0.12 | 0.12 | 0.24 |
| BaO + ZnO | | | | | | | |
| SnO₂ | 1.0 | 0 | 0 | 0.15 | 0 | 0 | 0.15 |
| TiO₂ + ZrO₂ | 1.19 | 0.54 | 0.66 | 0.64 | 1.23 | 0.66 | 0.54 |
| CeO₂ | 0.06 | 0.46 | 0.02 | 0.15 | 0.19 | 0.19 | 0.15 |
| F₂ | 1.41 | 0.09 | 0.51 | 2.53 | 2.59 | 2.59 | 0.22 |
| As₂O₃ + Sb₂O₃ | 0 | 0.17 | 0.35 | 0.05 | 0.33 | 0.33 | 0.17 |
| SiO₂/Al₂O₃ | 6.44 | 6.02 | 5.34 | 6.41 | 6.07 | 6.13 | 5.40 |
| (Na₂O + K₂O)/ | 1.15 | 4.75 | 2.3 | 4.55 | 4.5 | 4.5 | 4.75 |
| (MgO + CaO + | | | | | | | |
| SrO + BaO) | | | | | | | |
| α_{20/300} × 10⁻⁶/K) | 8.2 | 8.9 | 9.1 | 9.5 | 9.1 | 9.1 | 8.9 |
| Tg (° C.) | 595 | 632 | 618 | 565 | 573 | 579 | 626 |
| ST (° C.) | 832 | 863 | 845 | 811 | 821 | 822 | 860 |
| Δ ST-Tg | 237 | 231 | 227 | 246 | 248 | 243 | 234 |
| Electrical | 16.8 | 2.1 | 4.6 | 0.71 | 5.9 | 4.9 | 3.8 |
| conductivity | | | | | | | |
| (S/cm × 10⁻¹² 25° C.) | | | | | | | |
| Eletrical | 9.7 | 2.8 | 2.3 | 1.2 | 3.2 | 3.4 | 2.9 |
| conductivity | | | | | | | |
| (S/cm × 10⁻⁶, 250° C.) | | | | | | | |

The relatively high electrical conductivity at room temperature (typical values of glasses are in the range from 10⁻¹⁴ to 10⁻¹⁷S/cm; 25° C.), the high temperature dependence of the conductivity and the low activation energy of <1 eV measured on all exemplary glasses are a measure of the high sodium ion mobility of these substrate materials. In addition, it can be seen from the linear behavior of the temperature dependence of the electrical conductivity in the Arrhenius plot (FIG. 4; example 2=Glass 2; example 3=Glass 3) that only one species, namely Na⁺, determines the conductivity even though considerable amounts of K⁺ are also present.

The glasses not only can be used without deformation at temperatures of about 100° C.-150° C. above those of the prior art, but are also found to be reliable dopant sources for the crystallization process of, for example, I-III-VI₂ compound semiconductors such as CIGS due to the increased sodium ion mobility; these compound semiconductors can therefore grow to a higher degree of perfection in a temperature range which is about 100° C.-150° C. higher.

This high mobility is a prerequisite for the crystalline growth of the compound semiconductor layers, in particular the CIGS layers, and the photovoltaic properties which can then be achieved, if it is taken into account that the sodium ions must diffuse through a 0.5-1 μm thick molybdenum layer on the substrate glass before they reach the crystallization zone and/or must travel from the vapor phase as sodium atoms into the growing semiconductor layer.

The positive effect of the sodium ions on the chalcogen incorporation in the semiconductor crystal not only produces an improved crystalline structure and crystal density but also influences the crystalline size and orientation. The sodium ion is, inter alia, incorporated into the grain boundaries of the system and can contribute, inter alia, to a reduction in charge carrier recombination at the grain boundaries. These phenomena lead automatically to considerably improved semiconductor properties, in particular to a reduction in the recombination in the bulk material and thus to an increased open-circuit potential. This naturally shows up, in particular, in the efficiency with which the solar spectrum can be converted into electric power.

This ion mobility in the substrate glasses can be influenced further in a positive fashion by, preferably, a surface treatment in acidic or alkaline solutions, for example in such a way that ion mobility occurs earlier at relatively high temperatures or uniform diffusion of the sodium ions or more uniform evaporation of sodium from the surface is present.

Furthermore, it has surprisingly been found that a significant increase in the efficiency of a thin-film solar cell can be achieved in a simple manner when the solar cell has at least one Na₂O-containing multicomponent substrate glass which has the composition and properties as recited in the appended claims and is not phase demixed and has a content of β—OH of from 25 to 80 mmol/l. These substrate glass features include that the Na₂O-containing multicomponent substrate glass contains less than 1% by weight of B₂O₃, less than 1% by weight of BaO and a total of less than 3% by weight of CaO+SrO+ZnO, that the molar ratio of the substrate glass components, Na₂O+K₂O)/(MgO+CaO+SrO+BaO, is greater than 0.95, that the molar ratio of the substrate glass components SiO₂/Al₂O₃ is less than 7 and that the substrate glass has a glass transition temperature Tg of greater than 550° C., in particular greater than 600° C.

A substrate glass is not phase demixed for the purposes of the present invention when it has fewer than 10, preferably fewer than 5, surface defects in a surface region of 100×100 nm² after a conditioning experiment. The conditioning experiment was carried out as follows:

The substrate glass surface to be examined is subjected at 500-600° C. to a flow of compressed air in the range from 15 to 50 ml/min and a flow of sulphur dioxide gas (SO₂) in the range from 5 to 25 ml/min for a time of from 5 to 20 minutes. Regardless of the type of glass, this results in formation of a crystalline coating on the substrate glass. After washing off the crystalline coating (e. g, by means of water or an acidic or basic aqueous solution so that the surface is not attacked further), the surface defects per unit area of the substrate glass surface are determined by microscopy. If fewer than 10, in particular fewer than 5, surface defects are present in a surface region of 100×100 nm², the substrate glass is considered not to be phase demixed. All surface defects having a diameter of >5 nm are counted.

The β-OH content of the substrate glass was determined as follows. The apparatus used for the quantitative determination of water via the OH stretching vibration at 2700 nm is a commercial Nicolet FTIR spectrometer with attached computer evaluation. The absorption in the wavelength range 2500-6500 nm was firstly measured and the absorption maximum at 2700 nm was determined. The absorption coefficient a was then calculated from the specimen thickness d, the pure transmission T₁ and the reflection factor P:

α=1/d*Ig(1/Tᵢ)[cm⁻¹],

wherein Tᵢ=TIP with the transmission T. Then, the water content is calculated from c=α/e, wherein e is the practical extinction coefficient [l*mol⁻¹*cm⁻¹] and for the above-mentioned evaluation range is used as a constant value of e=110*mol*cm⁻¹ based on mol of H₂O. The e value is taken from the work by H. Frank and H. Scholze in “Glastechnischen Berichten”, Volume 36, No. 9, page 350.

### BRIEF DESCRIPTION OF THE DRAWING

The objects, features and advantages of the invention will now be illustrated in more detail, with reference to the accompanying figures in which:

FIG. 1 is a schematic cross-sectional view of an exemplary embodiment of a planar thin-film solar cell according to the invention;

FIG. 2 is a schematic cross-sectional view of a thin-flim solar module according to the invention protected against environmental influences by encapsulation;

FIG. 3 is a schematic cross-sectional view through an exemplary thin-film solar cell according to the invention coated on an inner tube of two coaxial glass tubes; and

FIG. 4 is a graphical illustration of the temperature dependence of the electrical conductivity in two examples of the substrate glass used in the solar cells according to the invention.

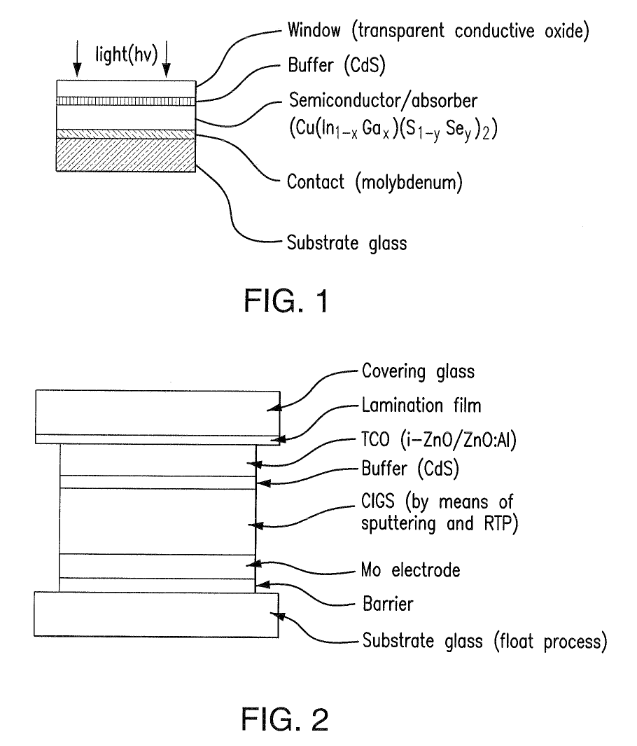

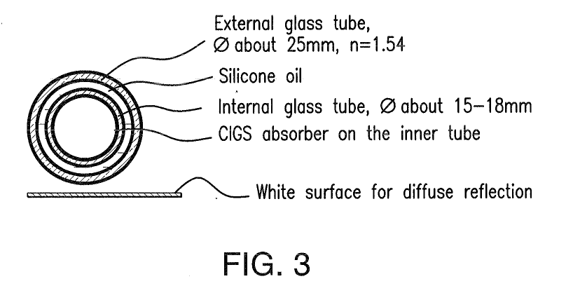

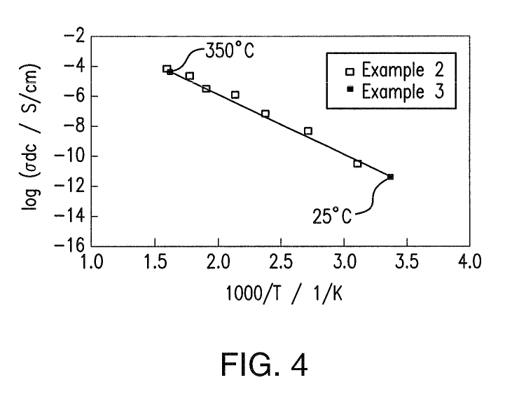

While the invention has been illustrated and described as embodied in thin-film solar cells, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A thin-film solar cell comprising at least one Na₂O-containing multicomponent substrate glass,
wherein the substrate glass contains less than 1% by weight of B₂O₃, less than 1% by weight of BaO and a sum total of less than 3% by weight of CaO+SrO+ZnO;
wherein a molar ratio of substrate glass components, (Na₂O+K₂O)/(MgO+CaO+SrO+BaO), is greater than 0.95;
wherein another molar ratio of the substrate glass components, SiO₂/Al₂O₃, is less than 7; and
wherein the substrate glass has a glass transition temperature Tg of greater than 550° C.

2. The solar cell as defined in claim 1, wherein said glass transition temperature Tg of the substrate glass is greater than 600° C.

3. The solar cell as defined in claim 1, wherein the substrate glass contains less than 0.5% by weight of said B₂O₃.

4. The solar cell as defined in claim 1, wherein the substrate glass does not contain said B₂O₃ apart from unavoidable traces.

5. The solar cell as defined in claim 1, wherein the substrate glass contains less than 0.5% by weight of said BaO.

6. The solar cell as defined in claim 1, wherein the substrate glass does not contain said BaO apart from unavoidable traces.

7. The solar cell as defined in claim 1, wherein the substrate glass contains less than a sum total of 2% by weight of said CaO+SrO+ZnO.

8. The solar cell as defined in claim 1, wherein the substrate glass contains at least 5% by weight of Na₂O.

9. The solar cell as defined in claim 1, wherein the substrate glass contains at least 8% by weight of Na₂O.

10. The solar cell as defined in claim 1, wherein said molar ratio of said substrate glass components, (Na₂O+K₂O)/(MgO+CaO+SrO+BaO), is less than 6.5.

11. The solar cell as defined in claim 1, wherein said another molar ratio of said substrate glass components, SiO₂/Al₂O₃, is less than 6 and greater than 5.

12. The solar cell as defined in claim 1, wherein said substrate glass has a coefficient of thermal expansion α_{20/300} of greater than 7.5×10⁻⁶/K in a temperature range from 20° C. to 300° C.

13. The solar cell as defined in claim 1, wherein said substrate glass has a coefficient of thermal expansion α_{20/300} from 8.0×10⁻⁶/K to 9.5×10⁻⁶/K in a temperature range from 20° C. to 300° C.

14. The solar cell as defined in claim 1, wherein said substrate glass has an electrical conductivity of greater than 17×10⁻¹² S/cm at 25° C. and the electrical conductivity of the substrate glass at 250° C. is a factor of 10⁴ greater than the electrical conductivity of the substrate glass at 25° C.

15. The solar cell as defined in claim 14, wherein said electrical conductivity of the substrate glass at 250° C. is a factor of 10⁵ greater than the electrical conductivity of the substrate glass at 25° C.

16. The solar cell as defined in claim 14, wherein said electrical conductivity of the substrate glass at 250° C. is a factor of 10⁶ greater than the electrical conductivity of the substrate glass at 25° C.

17. The solar cell as defined in claim 1, wherein sodium ions in the substrate glass are at least partly replaced by other cations to a surface depth of 20 μm, so that sodium ion content in a surface layer of the substrate glass is reduced compared to an overall sodium ion content of the substrate glass.

18. The solar cell as defined in claim 17, wherein said other cations include potassium ions.

19. The solar cell as defined in claim 1, wherein said substrate glass has a composition in mol % comprising:

| | |
|---|---|
| SiO₂ | 63-67.5 |
| Al₂O₃ | 10-12.5 |
| Na₂O | 8.5-15.5 |
| K₂O | 2.5-4.0 |
| MgO | 3.0-9.0 |
| CaO + SrO + ZnO | 0-2.5 |
| TiO₂ + ZrO₂ | 0.5-1.5 |
| CeO₂ | 0.02-0.5 |
| As₂O₃ + Sb₂O₃ | 0-0.4 |
| SnO₂ | 0-1.5 |
| F | 0.05-2.6; |

wherein components of the substrate glass are present in the glass in the following molar ratios:

| | |
|---|---|
| SiO₂/Al₂O₃ | 5.0-6.8 |
| Na₂O/K₂O | 2.1-6.2 |
| Al₂O₃/K₂O | 2.5-5.0 |
| Al₂O₃/Na₂O | 0.6-1.5 |
| (Na₂O + K₂O)/(MgO + CaO + SrO) | 0.95-6.5. |

20. The solar cell as defined in claim 1, wherein the substrate glass is coated with at least one molybdenum layer that is from 0.25 to 3.0 μm thick.

21. The solar cell as defined in claim 20, wherein the at least one molybdenum layer is from 0.5 to 1.5 μm thick.

22. The solar cell as defined in claim 1, which is based on silicon or based on compound semiconductor material selected from the group consisting of CdTe, CIS and CIGS.

23. The solar cell as defined in claim 1, which is planar, curved, spherical or cylindrical.

24. The solar cell as defined in claim 1, further comprising functional layers, and wherein said functional layers comprise conductive material, transparent conductive material, photosensitive compound semiconductor material, buffer material and/or metallic back contact material.

25. The solar cell as defined in claim 1, which is connected in series with at least one other solar cell and is encapsulated for protection against environmental influences.

26. The solar cell as defined in claim 25, which is encapsulated with an encapsulation material selected from the group consisting of SiO₂, plastics, surface coatings and another substrate glass.

27. The solar cell as defined in claim 26, wherein said encapsulation material is ethylene-vinyl acetate (EVA).

28. The solar cell as defined in claim 1, which comprises at least one photoactive semiconductor applied to the substrate glass or to a previously coated substrate glass at a temperature of >550° C.

29. The solar cell as defined in claim 1, wherein the substrate glass is not phase demixed and has a content of β—OH of from 25 to 80 mMol/l.
